(19) United States
(12) Patent Application Publication
(10) Pub. No.: US 2023/0035511 A1
(43) Pub. Date: Feb. 2, 2023

(54) LITHOGRAPHIC APPARATUS AND METHOD FOR DRIFT COMPENSATION

(71) Applicants: ASML NETHERLANDS B.V., Veldhoven (NL); ASML HOLDING N.V., Veldhoven (NL)

(72) Inventors: Ronny DER KINDEREN, Rosmalen (NL); Tian GANG, Best, (NL); Todd R. DOWNEY, Monroe, CT (US)

(73) Assignees: ASML NETHERLANDS B.V., Veldhoven (NL); ASML HOLDING N.V., Veldhoven (NL)

(21) Appl. No.: 17/791,641

(22) PCT Filed: Jan. 4, 2021
(86) PCT No.: PCT/EP2021/050024

§ 371 Date: Jul. 8, 2022

Related U.S. Application Data
(60) Provisional application No. 62/960,859, filed on Jan. 14, 2020.

(51) Int. Cl. G03F 7/20

(52) U.S. Cl. CPC G03F 7/70133; G03F 7/70558

(57) ABSTRACT

A system, method, a lithographic apparatus and a software product configured to determine a drift in an attribute of an illumination and a corresponding drift correction. The system includes a lithographic apparatus that includes at least two sensors, each configured to measure a property related to an illumination region provided for imaging a substrate. Furthermore, a processor is configured to: determine, based on a ratio of the measured property, a drift of the illumination region with respect to a reference position; determine, based on the drift of the illumination region, a drift in an attribute related to the illumination upstream of the illumination region measured by the at least two sensors, and determine, based on the drift in the attribute, the drift correction to be applied to the attribute to compensate for the drift in the attribute.

### CROSS-REFERENCE TO RELATED APPLICATIONS

This application claims priority of U.S. Provisional Patent Application No. 62/960,859, which was filed on Jan. 14, 2020, and which is incorporated herein in its entirety by reference.

### FIELD

The present disclosure relates to a lithographic apparatus and illumination uniformity correction system. The present disclosure generally relates to lithography, and more particularly to a system and method for compensating for uniformity drift caused by, for example, illumination beam movement, optical column uniformity, uniformity compensator drift, etc.

### BACKGROUND

A lithography apparatus is a machine that applies a desired pattern onto a target portion of a substrate. Lithography apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g. comprising part of, one or several dies) on a substrate (e.g. a silicon wafer) that has a layer of radiation-sensitive material (resist). In general, a single substrate contain a network of adjacent target portions that are successively exposed. Known lithography apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti parallel to this direction.

A lithographic apparatus typically includes an illumination system, which is arranged to condition radiation generated by a radiation source before the radiation is incident upon a patterning device. The illumination system may, for example, modify one or more properties of the radiation, such as polarization and/or illumination mode. The illumination system may include a uniformity correction system, which is arranged to correct or reduce non-uniformities, e.g., intensity non-uniformities, present in the radiation. The uniformity correction devices may employ actuated fingers which are inserted into an edge of a radiation beam to correct intensity variations. However, a width of a spatial period of intensity variation in that can be corrected is dependent on a size of an actuating device used to move fingers of the uniformity correction system. Furthermore, in some instances, if a size or shape of the fingers used to correct irregularities of a radiation beam is modified, then the uniformity correction system may compromise or modify in an unwanted manner one or more properties of the radiation beam, such as a pupil formed by the radiation beam.

To reduce manufacturing cost of ICs, it is customary to expose multiple substrates of each IC. Likewise, it is also customary that the lithographic apparatus is in almost constant use. That is, in order to keep manufacturing cost of all types of ICs at a potential minimum, the idle time between substrate exposures is also minimized. Thus, the lithographic apparatus absorbs heat which causes expansion of the apparatus's components leading to drift, movement, and uniformity changes.

In order to ensure good imaging quality on the patterning device and the substrate, a controlled uniformity of the illumination beam is maintained. That is, the illumination beam before reflecting off of or transmitting through the patterning device potentially has a non-uniform intensity profile. It is desirable to the entire lithographic process that the illumination beam be controlled with at least some uniformity. Uniformity can refer to a constant intensity across the entire illumination beam, but can also refer to the ability to control the illumination to a target illumination. The target illumination uniformity has a flat or a non-flat profile. The patterning device imparts to a beam of radiation a pattern, which is then imaged onto a substrate. Image quality of this projected radiation beam is affected by the uniformity of the illumination beam.

The market demands that the lithographic apparatus perform the lithography process as efficiently as possible to maximize manufacturing capacity and keep costs per device low. This means keeping manufacturing defects to a minimum, which is why the effect of the uniformity of the illumination beam may be minimized as much as practical.

### SUMMARY

In an embodiment, there is provided a system including a lithographic apparatus that includes at least two sensors, each configured to measure a property related to an illumination region provided for imaging a substrate; and a processor configured to determine a drift in an attribute related to an illumination. The processor is configured to: determine, based on a ratio of the measured property as measured by one of the sensors in relation to the other, a drift of the illumination region with respect to a reference position; determine, based on the drift of the illumination region, a drift in an attribute related to the illumination upstream of the illumination region measured by the at least two sensors, and determine, based the drift in the attribute, the drift correction to be applied to the attribute to compensate for the drift in the attribute.

In an embodiment, there is provided a method of determining a drift correction associated with a lithographic apparatus. The method includes receiving, via at least two sensors, measurements of a property related to an illumination region provided for imaging a substrate; determining, based on a ratio of the measured properties, a drift of the illumination region with respect to a reference position; determining, based on the drift of the illumination region, a drift in an attribute related to the illumination upstream of the illumination region measured by the at least two sensors, and determining, based the drift in the attribute, the drift correction to be applied to the attribute to compensate for the drift in the attribute.

Furthermore, in an embodiment, there is provided a non-transitory computer-readable media comprising instructions that, when executed by one or more processors, cause operations of the method discussed herein.

Furthermore, in an embodiment, there is provided a lithography apparatus. The apparatus including an illumination source and illumination optics configured to image a substrate; and at least two sensors configured to measure a property related to an illumination region provided for imaging the substrate; and a processor configured to determine a drift in an attribute related to the illumination. The processor is configured to: determine, based on a ratio of the measured properties, a drift of the illumination region with respect to a reference position; determine, based on the drift of the illumination region, a drift in a attribute related to the illumination upstream of the illumination region measured by the at least two sensors, and determine, based the drift in the attribute, a drift correction to be applied to the attribute to compensate for the drift in the attribute. A uniformity compensator system is also provided that includes one or more uniformity compensators in one or more locations in a path of the illumination region to intercept one or more corresponding portions of the illumination region in the one or more locations. A uniformity sensitivity model determines, based on the drift of the illumination region or the drift in the attribute, an amount of adjustment to the one or more uniformity compensators to correct for the drift in the attribute.

### BRIEF DESCRIPTION OF THE DRAWINGS

Embodiments will now be described, by way of example only, with reference to the accompanying drawings in which:

FIG. 1 is a diagram of an exemplary lithographic projection apparatus, according to an embodiment;

FIG. 2 is another exemplary lithographic apparatus, according to an embodiment;

FIG. 3 shows an example of a uniformity compensators with respect to the illumination beam slit, according to an embodiment;

FIG. 4 illustrates example positions of two sensors with respect to each other and with respect to an energy sensor in an illumination of the lithographic apparatus (e.g., FIGS. 1 and 2), according to an embodiment;

FIG. 5 is a flow chart of a method for determining a drift correction associated with imaging of a wafer or each wafer within a lot, according to an embodiment;

FIG. 6 is a block diagram of an exemplary computer system, according to an embodiment;

FIG. 7 is a diagram of an exemplary extreme ultraviolet (EUV) lithographic projection apparatus, according to an embodiment;

FIG. 8 is a more detailed view of the exemplary apparatus in FIG. 7, according to an embodiment; and

FIG. 9 is a more detailed view of the source collector module of the apparatus of FIG. 7 and FIG. 8, according to an embodiment.

### DETAILED DESCRIPTION

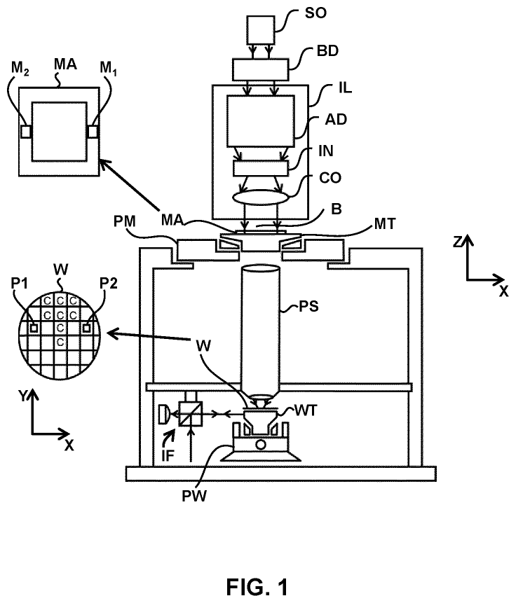

FIG. 1 depicts an exemplary lithographic projection apparatus in conjunction with the techniques described herein can be utilized in accordance with an embodiment of the present disclosure. The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 1 that the source SO may be an integral part of, e.g., within the housing of, the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g. so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 1. However, in the case of a stepper (as opposed to a step-and-scan tool) the patterning device table MT may just be connected to a short stroke actuator, or may be fixed.

The illumination system IL may include various types of optical components, such as refractive, reflective, magnetic, electromagnetic, electrostatic, or other types of optical components, or any combination thereof, for directing, shaping, or controlling the radiation B. The illumination system IL may also include an energy sensor ES that provides a measurement of the energy (per pulse), a measurement sensor for measuring the movement of the optical beam, and uniformity compensators UC that allow the illumination slit uniformity to be controlled.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.
In another mode, the mask table MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

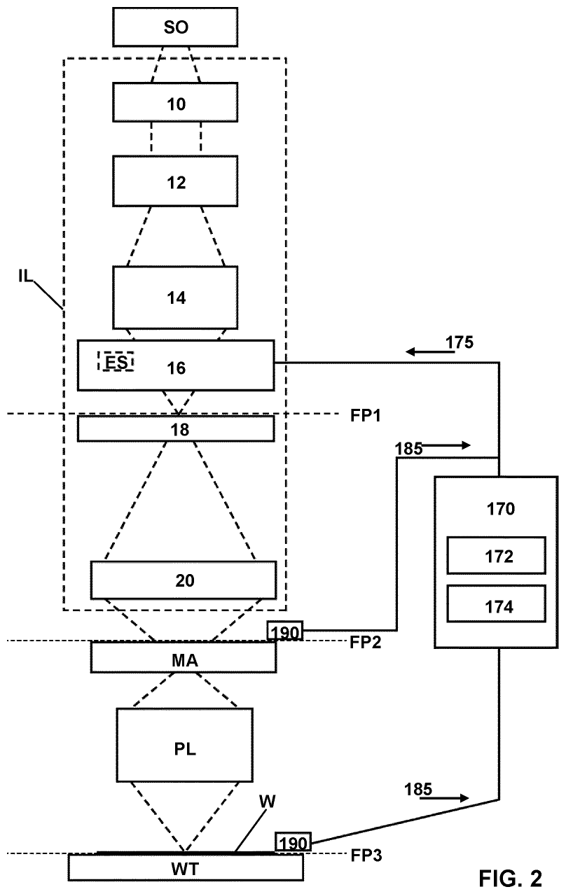

FIG. 2 depicts a lithographic apparatus, according to an embodiment of the invention. In the example shown, the lithographic apparatus can include a source SO, an illumination system IL, a support structure (not shown) configured to hold a patterning device MA, a projection system PL, a substrate table WT, a correction module 170, one or more measurement devices 190, and a substrate W located on the substrate table WT.

In one example, illumination system IL can include a collimator 10, a field defining element 12, a field lens group 14, uniformity correction system 16, reticle masking blades 18 and a condensing lens 20. The illumination system IL may also include an energy sensor ES that provides a measurement of the energy (per pulse), a measurement sensor for measuring the movement of the optical beam, and uniformity compensators UC that allow the illumination slit uniformity to be controlled. In an embodiment, the illumination system IL includes an illumination uniformity correction module (UNICOM). Signals from sensors (e.g., ES at reticle level) are used to control the UNICOM module to trim the illumination slit, so as to compensate for non-uniformities in illumination.

In one example, collimator 10 can be used to collimate a radiation beam generated by the source SO (the beam is schematically indicated by dashed lines). Field defining element 12 can form the radiation beam into a field shape, which will be projected onto the substrate W. The field defining element may, for example, comprise two arrays of convex lenses, the second array being placed in the focal plane of the first array.

In one example, field lens group 14 can focus the radiation beam onto a field plane FP1. In this example, the masking blades 18, which comprise a pair of blades moveable in the scanning direction of the lithographic apparatus, are located in the field plane FP1.

In one example, the masking blades 18 can be used to ensure that, during exposure of a given target area, radiation is not incident upon a target area that is adjacent in the y- and/or x-direction to the given target area. The masking blades 18 are located in the field plane FP1 so that masking provided by the masking blades 18 can be translated accurately (and with sharp edges) onto the patterning device MA.

In one example, a uniformity correction system 16 is located before the masking blades 18 in the path of the radiation beam, so that the radiation beam can pass through the uniformity correction system before the radiation beam is incident upon the masking blades 18. The uniformity correction system 16 is therefore not located in the field plane FP1, but instead is displaced from it. Uniformity correction system 16 can spatially control an intensity of the radiation beam, i.e., uniformity correction system 16 can spatially control the intensity of the radiation in the field shape which will be projected onto the substrate W. In an embodiment, the uniformity correction system 16 includes at least one array of overlapping fingers and/or at least one array of non-overlapping fingers that can be movable into and out of intersection with a radiation beam incident on the fingers, so as to selectively correct an intensity of portions of the radiation beam. It is to be appreciated that although seven fingers are shown in each bank, any number of fingers can be used. The term of bank of fingers, finger bank or bank may be used interchangeably throughout the present application.

In one example, after passing through the masking blades 18 the radiation beam is incident upon condensing lens 20. Condensing lens 20 can focus the radiation onto another field plane FP2. The patterning device MA, which is located in field plane FP2, can apply a pattern to the radiation beam.

In one example, the patterned radiation beam passes through the projection system PL and onto the substrate W. The substrate W is located in a further field plane FP3. The projected pattern beam transfers the pattern onto the substrate.

In one example, correction module 170 can determine adjustments to the variables of correction system 16, such that the desired uniformity specification is met. Correction module 170 can determine one or more correction parameters 175 based on the determined adjustments and communicates these parameters to correction system 16. The correction parameters control adjustable variables within correction system 16. Correction module 170 may also receive illumination field data 185 collected from one or more uniformity measurement devices 190 positioned at the field plane FP3 or field plane FP2 of patterning device MA.

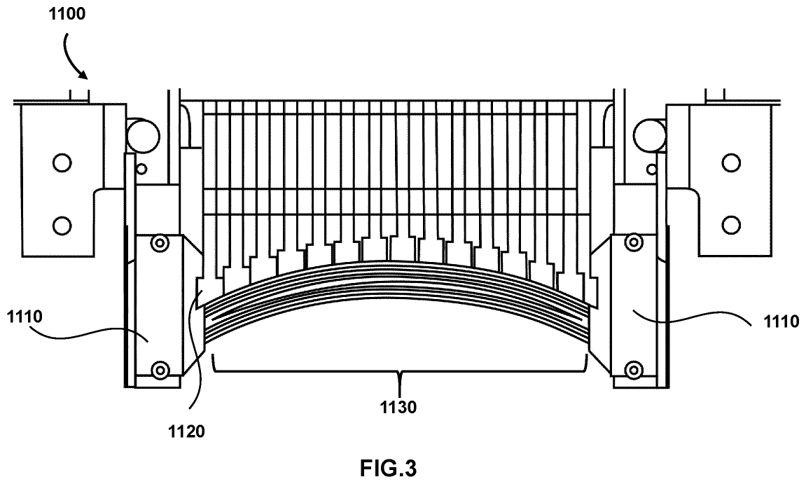

Through manipulation of the adjustable variables of correction system 16 in accordance with the correction parameters, characteristics of the illumination beam can be changed. More specifically, the correction parameters can provide details on how to adjust the variables of correction system 16 to achieve the desired uniformity profile (e.g., flattest uniformity or shape beneficial for the lithography process). For example, correction parameters may describe which fingers in a one or more banks of fingers (e.g., plurality of uniformity compensators 1120 in FIG. 3) need to be moved and to what distance they need to moved into or out of intersection with an incident beam of radiation so as to selectively correct an intensity of portions of the radiation beam incident on uniformity correction system 16.

In one example, correction module 170 can include one or more processors 172 and memory 174. One or more processors 172 can execute software that causes uniformity correction system 16 to adjust variables to achieve desired uniformity criteria for a beam of radiation. Memory 174 can include a main memory (e.g., a random access memory (RAM)). In an embodiment, memory 174 also includes a secondary memory. Secondary memory can include, for example, a hard disk drive and/or a removable storage drive. Computer programs can be stored in memory 174. Such computer programs, when executed, can allow processor 172 in correction module 170 to perform the features of an embodiment of the present invention, as discussed herein. In an embodiment, where the method for adjusting elements of uniformity correction system 16 are implemented using software, the software can be stored in a computer program product and loaded into correction module 170 using a removable storage device, a hard drive, or a communications interface. Alternatively, the computer program product can be downloaded to correction module 170 via a communications path. In addition, in an embodiment, the correction module 170 is coupled to one or more remote processors. The correction module 170 can then receive instructions and/or operating parameters remotely.

FIG. 3 illustrates a mechanical portion of a uniformity refresh (UR) correction system 1100, according to an embodiment of the present invention. In FIG. 3, the uniformity refresh (UR) correction system 1100 includes energy sensors (ES) 1110 and a plurality of uniformity compensators 1120. UR correction system 1100 can modify the illumination beam during a lithographic operation. In at least one embodiment of the present disclosure, the illumination beam is shaped in an arc shape and is referred to as an illumination slit 1130. By controlling movement of the individual uniformity compensators 1120 into and out of the illumination slit 1130, the uniformity of the illumination slit 1130 can be controlled. The uniformity compensators 1120 may also be referred to as fingers. An example operation of uniformity compensators may be found in commonly owned, co-pending U.S. Pat. No. 8,629,973, which is incorporated herein by reference in its entirety.

In one example, the fingers shown in FIG. 3 may be individually controlled to modify the intensity of the illumination slit in order to achieve a target uniformity.

Example methods of controlling an illumination slit profile are discussed in U.S. Pat. No. 8,629,973, which is incorporated herein by reference in its entirety. In an embodiment, the uniformity correction is based on a first set of inputs can relate to a curve representing a targeted flat profile with the finger at their center positions and a value of uniformity measurement with the fingers at their center positions. A second set of inputs can relate to a curve representing an amount of attenuation per insertion location of the finger into the illumination beam and a value of current finger positions and corresponding attenuation values. In one example, the uniformity refresh correction system method starts at a beginning of each lot of substrates. In one step, the illumination slit uniformity is measured (e.g., by slit integrated intensity or by slit-scan average using discrete intensity samples along the slit). The uniformity refresh (UR) correction system calculates uniformity compensators (e.g., fingers) positions based on a flat intensity profile across the slit. Optionally, the uniformity refresh (UR) correction system calculates uniformity compensators (e.g., fingers) positions based on a non-flat (a.k.a., DOSEMAPPER® or DoMa) intensity profile. Examples regarding DOSEMAPPER® embodiments may be found in U.S. Pat. No. 7,532,308, issued May 12, 2009, which is incorporated herein by reference in its entirety.

Another example, an apparatus and method of dynamically adjusting the illumination field for providing a desired exposure to control and reduce line width variations is discussed in U.S. Pat. No. 6,097,474, which is incorporated herein by reference in its entirety. The patent describes an exposure calculator coupled to said drive control, said exposure calculator providing said drive control with drive signals controlling the movement of each of said plurality of adjustable finger (or links) into and out of the illumination field so as to provide a predetermined adjusted exposure dose. For example, when a variety of different line widths are desired to be imaged, the exposure dose is varied as a function of the line width. The preferred exposure dose can be calculated based on existing techniques and may consider variables such as type of resist, substrate material, illumination energy, illumination wavelength, scanning speed, among others.

The thermal heat load on the illumination system within a lot leads to dose drift. In the existing technology, the magnitude of the dose drift and the consequence imaging yield is acceptable. For future higher powers, e.g., a lithographic apparatus having greater than or equal to 400 W and even greater than or equal to 1 kW, it would increase the heat load by approximately more than two times. Such higher powers results in stronger dose drift which deteriorate the imaging yield.

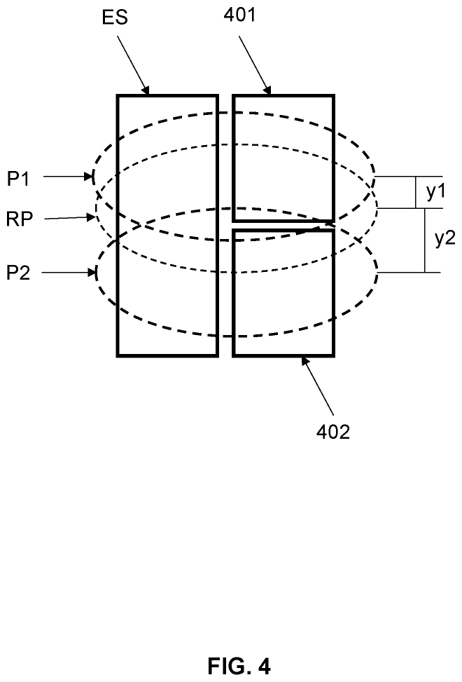

The existing technology includes single diode energy sensor for closing an energy loop with the illuminator source by measuring intensity at both sides of the illumination slit. This single energy sensor measures full slit intensity (per pulse). In the present disclosure, additional sensors are included (e.g., sensors 401 and 402 in FIG. 4) to measure e.g., Y-position of the illumination slit per wafer. The measurements from the additional sensors provide inputs to correct corresponding dose drift with UNICOM finger adjustment per wafer; during chuck swap.

The present disclosure proposes usage of multi-faceted energy sensors (e.g., 401 and 402) to measure slit position drift during the lot enabling within lot dose drift correction via UNICOM, without requiring a throughput limiting UR per wafer.

The present disclosure provides several advantages including improvement in the dose drift during the lot. For example, in existing technology, the dose drift within the lot due to thermal heating effects inside the illuminator may be significantly out of specification (˜2×) for powers greater than (or equal to) 500 W, that will result in imaging loss during the lot. Thus, reducing the dose drift during imaging of, e.g., one or more (or each) wafer within the lot, the imaging performance can be improved.

In an embodiment, by continuously measuring the illumination slit position from the moment the lot starts (so during the Uniformity Refresh or slit integrated energy (SLIE) measurement) with a multi-faceted energy sensor, one can correct for a dose drift during the lot using a UNICOM correction per wafer (or even more frequent, if desired). When the next lot starts by default a new UR is done, and the correction cycle within the lot, using the mulit-faceted ES can start again.

In an embodiment of the present disclosure, the lithographic apparatus includes energy sensor which consist of two facets e.g., configured to measure Y-position of the slit per wafer. For example, an initial ratio of the two facets may be measured or determined during the UNICOM Refresh or a start of a lot. Further, any change in the initial ratio may be tracked during the lot (e.g., over a 15 min interval) to measure a drift of the slit position. Based on the slit drift and an existing UNICOM sensitivity, correction for a corresponding dose drift may be made by applying a UNICOM correction per wafer. The main advantage is that this can be done without actually having to perform an additional Uniformity Refresh per wafer. In an embodiment, such sensor can also determine the slit position drift in x using ratio of ES/(measurements of 401+measurements of 402). This can be used for Uniformity correction if needed.

FIG. 4 illustrates example positions of two sensors with respect to each other and with respect to an energy sensor in an illumination of the lithographic apparatus (e.g., FIGS. 1 and 2). The two sensors are an example of a multi-faceted energy sensor that is configured to determine a slit drift of a lithographic apparatus (e.g., DUV, EUV, etc.). According to an embodiment, the sensors 401 and 402 can be configured to measure a property of an illumination region (e.g., an illumination slit) (represented as dotted ovals), and a ratio of the properties can be used to determine a drift of the illumination region. For example, as shown, an illumination slit can drift between positions P1, P2, and RP for each wafer within a lot due to dose drift during a patterning process. In an embodiment, the measured property can be intensity of a portion of the illumination region. A ratio of the measured property is tracked to determine a drift in a position of e.g., the illumination slit with respect to a reference position RP.

As shown in FIG. 4, at position RP of the illumination region (e.g., an illumination slit), the sensor 401 detects intensity of a portion of the illumination slit and sensor 402 detects intensity of another portion of the same illumination slit. The ratio of detected intensity can be, for example, 100. As the patterning process progresses, the slit may drift to the position P1. At position P1, the ratio of measured intensities by sensors 401 and 402 will change. For example, the ratio can be 900. Then, the ratios at positions P1 and RP can be compared to determine a drift of the illumination slit (e.g., y1). For example, a change in ratio 100 (i.e., 1000-900) can be indicative of a drift of the illumination slit of y1 nm (e.g., 2 nm). In another example, the slit may drift to the position P2. At position P2, the ratio of measured intensities by sensors 401 and 402 will change. For example, the ratio can be 1100. Then, the ratios at positions P2 and RP can be compared to determine a drift of the illumination slit (e.g., y2). For example, a change in the ratio −100 (i.e., 1000-1100) can be indicative of a drift of the illumination slit of y2 nm (e.g., −2 nm).

In an embodiment, a relationship between the drift of the illumination slit and the ratio of properties measured by the two sensors may be established by experimentation or test wafers. Then, such relationship can be used during the patterning process to determine, based on the ratio of property, the drift of the illumination slit. Further, based on the drift of the illumination slit, a dose drift can be determined using existing relationships between the drift of the illumination slit and the dose drift. Similarly, a drift in other attributes related to source or pupil may be determined based on the drift of the illumination slit.

It can be understood the present system or methods are not limited to two sensors (e.g., 401 and 402). A person of ordinary skill in the art can modify the system to include three, four, or more sensors placed adjacent to each other and around the illumination slit. Such positioning of sensors generates a multi-faceted sensor where each sensor may detect a portion of the illumination and a ratio between different measurements can be taken and tracked to determine drift of the illumination slit e.g., a drift in the slit position with respect to an initial position or reference position. The drift of the illumination slit may be caused due to a dose drift or a pupil drift (e.g., a change in pupil shape). Hence, appropriate corrections can be applied to source or pupil so reduce the dose drift or the pupil drift, which in turn will reduce the drift of the illumination slit. These dose or pupil corrections can improve imaging performance of the lithographic apparatus without affecting the throughput of the patterning process.

In describing the sensors 401 and 402 as being “at reticle level”, or “in the vicinity of the patterning device”, no fixed threshold of proximity to the patterning device is intended. However, the purpose of the sensors is to detect a shift in illumination slit that has not been corrected in the illumination conditioning optics of the illumination module IL. The sensors may be located between the UNICOM and the patterning device. In an embodiment, the sensors could be arranged to detect radiation reflected by peripheral portions of the patterning device.

In an embodiment, the present disclosure describes a system including a lithographic apparatus and a processor configured to determine a drift correction associated with a lithographic apparatus. The system includes a lithographic apparatus (e.g., FIG. 2) having at least two sensors (e.g., 401 and 402 in FIG. 4) configured to measure a property related to an illumination slit provided for imaging a wafer, and a processor (e.g., a processor 104 of FIG. 1 or a processor which is part of the sensors 401 and 402) configured to determine a drift of the illumination slit, a drift in an attribute (e.g., dose drift) and a correction related to the drift in the attribute. In an embodiment, the measured properties are illumination intensity values measured by a first sensor (e.g., 401) and a second sensor (e.g., 401), respectively, of the at least two sensors.

In an embodiment, the at least two sensors comprises the first sensor 401 located at a first location (e.g., at 1110 on a left side) of the illumination slit and the second sensor 402 located at a second location (e.g., at 1110 on a left side) of the illumination slit. In an embodiment, the attribute to be corrected is dose and/or pupil of the lithographic apparatus (e.g., FIGS. 1, 2, and 7). Accordingly, the drift in the attribute can be a dose drift with respect to a nominal dose, and/or a pupil drift with respect to a reference pupil. Thus, the drift correction can be a dose drift correction or a pupil drift correction.

It can be understood by a person of ordinary skill in the art that the system (e.g., FIG. 2) is not limited to location of a processor or the sensors 401 and 402. For example, the sensors may be located at different locations along the illumination slit. In an embodiment, the sensors may be located before the reticle stage. In another example, additional sensors may be placed after the reticle stage.

In an embodiment, the processor is configured to: determine, based on a ratio of the measured properties, a drift of the illumination slit of the illumination slit with respect to a reference position of the illumination slit; determine, based on the drift of the illumination slit, a drift in an attribute related to the illumination upstream of the illumination region measured by the at least two sensors. For example, the attributes are related to an illumination source and/or a pupil of the lithographic used for imaging the wafer. For example, in FIGS. 1, 2, 7 and 8, energy sensor ES and uniformity compensator UC may be considered upstream and the attributes are related to illumination source and/or pupil upstream of ES, for example. Further, the processor determines, based the drift in the attribute, the drift correction to be applied to the illumination source or the pupil to compensate for the drift in the attribute. In an embodiment, the drift in the attribute is caused by one or both of illumination optics collector contamination and an amount of power of the illumination source.

In an embodiment, the reference position is a slit position measured at a start of an imaging of a wafer in a lot. In an embodiment, the reference position is at a center of the slit.

In an embodiment, the drift correction is determined using a uniformity compensator system (e.g., shown in FIG. 3). In an embodiment, the first sensor is located at a first end of the uniformity compensator system and the second sensor is located at a second end of the uniformity compensator system. In an embodiment, the uniformity compensator system comprises one or more uniformity compensators in one or more locations in a path of the illumination slit to intercept one or more corresponding portions of the illumination slit in the one or more locations. In an embodiment, the one or more uniformity compensators comprise one or more opaque finger members.

Furthermore, a uniformity sensitivity model determines, based on the drift of the illumination slit or the drift in the attribute, an amount of adjustment to the one or more uniformity compensators to correct for the drift in the attribute. In an embodiment, the drift in the attribute is caused by one or both of illumination optics collector contamination and an amount of power of the illumination source. In an embodiment, the drift in the attribute is determined by converting, based on a correlation between the drift of the illumination slit and the drift in the attribute, the drift of the illumination slit to the drift in the attribute.

In an embodiment, the drift correction is determined for each wafer within a lot. Hence, each wafer within the lot may be corrected for, e.g., a dose drift that may cause a drift of the illumination slit. This correction results in an improved imaging performance of the lot. This is different from the typical uniformity refresh process, where a drift correction is performed at the start of each lot.

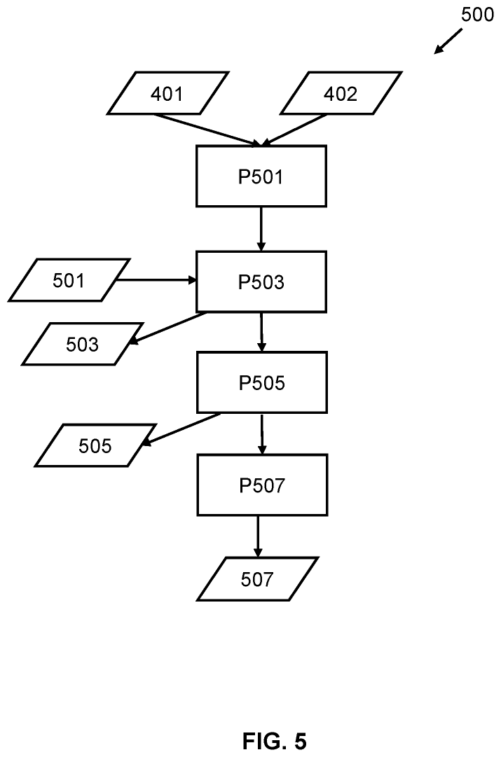

FIG. 5 is a flow chart of a method 500 of determining a drift correction associated with a lithographic apparatus used for imaging wafers of a lot. The method 500 includes, at process P501, receiving, via at least two sensors 401 and 402, measurements of a property related to an illumination slit provided for imaging a wafer within the lot. In an embodiment, the at least two sensors comprises a first sensor located at a first location of the illumination slit and a second sensor located at a second location of the illumination slit. Example position of the sensors 401 and 402 is discussed with respect to FIG. 4. In an embodiment, the measured properties are illumination intensity values measured by a first sensor and a second sensor, respectively, of the at least two sensors.

At process P503, the method includes determining, based on a ratio 501 of the measured properties, a drift 503 of the illumination slit (also referred as a drift of the illumination slit 503) with respect to a reference position (e.g., RP in FIG. 4) of the illumination slit. In an embodiment, the reference position (e.g., RP in FIG. 4) is a slit position measured at a start of an imaging of a first wafer in a lot. In an example, the reference position is at a center of the slit. Example of determining drift of the illumination slit is discussed with respect to FIG. 4. For example, the drift of the illumination slit 503 can be determined by tracking a change in the ratio 501 with respect to a reference ratio determined at the first wafer of the lot.

At process P505, the method includes determining, based on the drift of the illumination slit 503, a drift 505 in an attribute related to the illumination source or a pupil used for imaging the wafer. In an embodiment, the drift 505 in the attribute is determined by converting, based on a correlation between the drift of the illumination slit 503 and the drift 505 in the attribute, the drift of the illumination slit 503 to the drift 505 in the attribute. In an embodiment, the correlation can be established based on test wafers, or an existing correlation between e.g., the drift of the illumination slit and the dose drift may be employed. For example, the drift of the illumination slit 503 can be used to determine the dose drift 505 based on an existing relationship between a drift of the illumination slit and a dose drift.

At process P507, the method includes determining, based the drift 505 in the attribute, the drift correction 507 to be applied to the illumination source or the pupil to compensate for the drift 505 in the attribute. In an embodiment, the drift correction 507 is determined for each wafer within a lot. Hence, each wafer within the lot may be corrected for, e.g., a dose drift that may cause a drift of the illumination slit. This correction results in an improved imaging performance of the lot. This is different from the typical uniformity refresh process, where a drift correction is performed at the start of each lot.

In an embodiment, the attribute can be dose and/or pupil of the lithographic apparatus used for imaging the wafer. Accordingly, the drift 505 in the attribute can be a dose drift with respect to a nominal dose, and/or a pupil drift with respect to a reference pupil. The drift correction 507 can be a dose drift correction or a pupil drift correction.

In an embodiment, the determining of the correction 507 to be applied to the illumination source or the illumination pupil includes executing a uniformity sensitivity model (e.g., implemented in a UNICOM module of the Uniformity correction system in FIG. 2) using the drift 505 in the attribute to determine adjustments to one or more uniformity compensators. The uniformity sensitivity model determines, based on the drift of the illumination slit 503 or the drift 505 in the attribute, an amount of adjustment to the one or more uniformity compensators (e.g., 1120) to correct for the drift in the attribute. In an embodiment, the drift correction for the drift in the attribute includes positioning the one or more uniformity compensators in one or more locations in a path of the illumination slit to intercept one or more corresponding portions of the illumination slit in the one or more locations. As mentioned earlier, the one or more uniformity compensators comprise one or more opaque finger members. Also, as discussed earlier, a first sensor can be located at a first end of a uniformity compensator and a second sensor can be located at a second end of the uniformity compensator.

In an embodiment, there is provided a lithography apparatus (e.g., shown in FIGS. 1, 2, and 7). According to the present disclosure, the lithographic apparatus (e.g., shown in FIGS. 1, 2, and 7) includes an illumination source and illumination optics configured to image a wafer; and at least two sensors configured to measure a property related to an illumination slit provided for imaging the wafer; a processor configured to determine a drift of the illumination slit, a drift in a attribute (e.g., dose or pupil) of the lithographic apparatus. For example, the processor is configured to determine, based on a ratio of the measured properties, a drift of the illumination slit of the illumination slit with respect to a reference position of the illumination slit; and determine, based on the drift of the illumination slit, a drift in a attribute related to the illumination source or a illumination pupil used for imaging the wafer, and determine, based the drift in the attribute, a drift correction to be applied to the illumination source or the illumination pupil to compensate for the drift in the attribute.

Furthermore, the lithographic apparatus includes a uniformity compensator system (e.g., shown in FIG. 3). The uniformity compensator system includes one or more uniformity compensators in one or more locations in a path of the illumination slit to intercept one or more corresponding portions of the illumination slit in the one or more locations. A uniformity sensitivity model determines, based on the drift of the illumination slit or the drift in the attribute, an amount of adjustment to the one or more uniformity compensators to correct for the drift in the attribute.

In an embodiment the drift correction is determined and applied for each wafer within the lot that are processed at the lithographic apparatus. In an embodiment, the at least two sensors comprises a first sensor located at a first location of the illumination slit and a second sensor located at a second location of the illumination slit. In an embodiment, a first sensor is located at a first end of the uniformity compensator system and a second sensor is located at a second end of the uniformity compensator system. In an embodiment, the at least two sensors are located in a vicinity of an energy sensor that measures an intensity of the illumination slit.

In an embodiment, the attribute can be dose and/or pupil of the lithographic apparatus. Accordingly, the drift in the attribute can be a dose drift with respect to a nominal dose, and/or a pupil drift with respect to a reference pupil, and the drift correction can be a dose drift correction or a pupil drift correction.

In an embodiment, the methods discussed herein may be provided as a computer program product or a non-transitory computer readable medium having instructions recorded thereon, the instructions when executed by a computer implementing the operation of the method 500 discussed above.

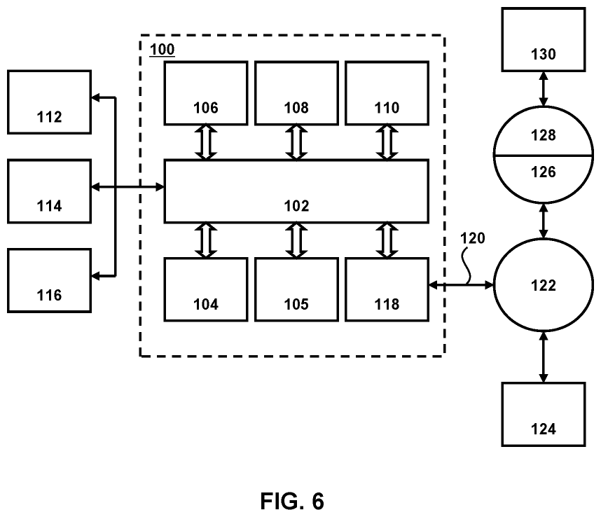

For example, an example computer system 100 in FIG. 6 includes a non-transitory computer-readable media (e.g., memory) comprising instructions that, when executed by one or more processors (e.g., 104), cause the computer to receive, via at least two sensors, measurements of a property related to an illumination slit provided for imaging a wafer; determine, based on a ratio of the measured properties, a drift of the illumination slit of the illumination slit with respect to a reference position of the illumination slit; determine, based on the drift of the illumination slit, a drift in an attribute related to the illumination upstream of the illumination region measured by the at least two sensors. For example, the attributes are related to an illumination source or a pupil used for imaging the wafer. Further, the processor determines, based the drift in the attribute, a drift correction to be applied to the illumination source or the pupil to compensate for the drift in the attribute. In an embodiment, the at least two sensors comprises a first sensor located at a first location of the illumination slit and a second sensor located at a second location of the illumination slit.

In an embodiment, the measured properties are illumination intensity values measured by a first sensor and a second sensor, respectively, of the at least two sensors.

In an embodiment, the reference position is a slit position measured at a start of an imaging of a wafer in a lot. In an embodiment, the reference position is at a center of the illumination slit.

In an embodiment, the attribute is dose and/or pupil. Accordingly, the drift in the attribute is a dose drift with respect to a nominal dose, and/or a pupil drift with respect to a reference pupil, and the drift correction is a dose drift correction or a pupil drift correction.

In an embodiment, the non-transitory computer readable medium determines the drift correction for each wafer within a lot.

In an embodiment, the non-transitory computer readable medium determines the drift in the attribute by converting, based on a correlation between the drift of the illumination slit and the drift in the attribute, the drift of the illumination slit to the drift in the attribute.

In an embodiment, the non-transitory computer readable medium determines the correction to be applied to the illumination source or the illumination pupil by: executing a uniformity sensitivity model using the drift in the attribute to determine adjustments to a uniformity compensator. The uniformity sensitivity model determines, based on the drift of the illumination slit or the drift in the attribute, an amount of adjustment to one or more uniformity compensators to correct for the drift in the attribute.

In an embodiment, the non-transitory computer readable medium determines positioning the one or more uniformity compensators in one or more locations in a path of the illumination slit to intercept one or more corresponding portions of the illumination slit in the one or more locations. In an embodiment, the one or more uniformity compensators comprise one or more opaque finger members.

In an embodiment, a first sensor is located at a first end of a uniformity compensator and a second sensor is located at a second end of the uniformity compensator.

FIG. 6 is a block diagram that illustrates an exemplary computer system 100 configured to assist in implementing methods and flows disclosed herein in accordance with an embodiment of the present disclosure. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also desirably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are example forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

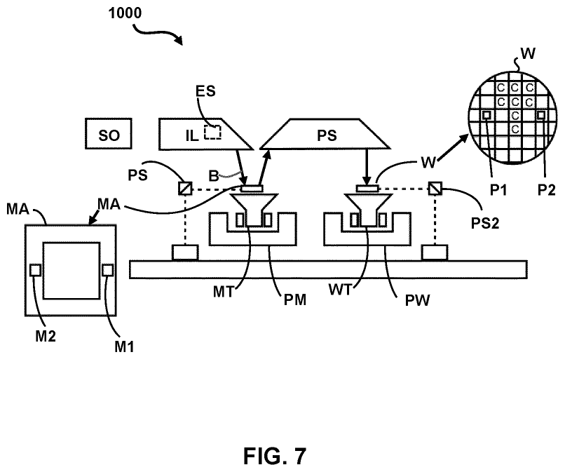

FIG. 7 depicts another exemplary lithographic projection apparatus 1000 in accordance with an embodiment of the present disclosure. Apparatus 1000 includes:
a source collector module SO to provide radiation.
an illumination system (illuminator) IL configured to condition a radiation beam B (e.g. EUV radiation) from the source collector module SO.
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus 1000 is of a reflective type (e.g. employing a reflective mask). It is to be noted that because most materials are absorptive within the EUV wavelength range, the patterning device may have multilayer reflectors comprising, for example, a multi-layer stack of molybdenum and silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 7, the illuminator IL receives an extreme ultra violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 7, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the radiation source may be an integral part of the source collector module, for example when the radiation source is a discharge produced plasma EUV generator, often termed as a DPP radiation source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus 1000 could be used in at least one of the following modes:

1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.
2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.
3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

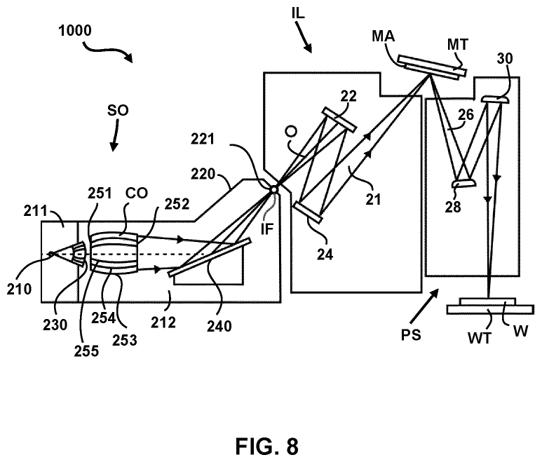

FIG. 8 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma radiation source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘0’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the Figures, for example there may be 1-6 additional reflective elements present in the projection system PS than shown in FIG. 8.

Collector optic CO, as illustrated in FIG. 8, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type is desirably used in combination with a discharge produced plasma radiation source.

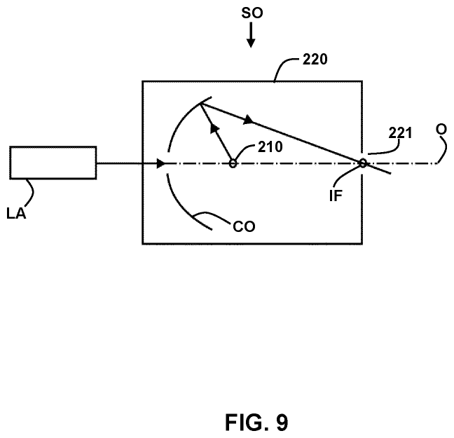

Alternatively, the source collector module SO may be part of an LPP radiation system as shown in FIG. 9. A laser LAS is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing wavelengths of an increasingly smaller size. Emerging technologies already in use include EUV (extreme ultra violet) lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

Although specific reference may be made in this text to the use of embodiments in the manufacture of ICs, it should be understood that the embodiments herein may have many other possible applications. For example, it may be employed in the manufacture of integrated optical systems, guidance and detection patterns for magnetic domain memories, liquid-crystal displays (LCDs), thin film magnetic heads, micromechanical systems (MEMs), etc. The skilled artisan will appreciate that, in the context of such alternative applications, any use of the terms “reticle”, “wafer” or “die” herein may be considered as synonymous or interchangeable with the more general terms “patterning device”, “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create, for example, a multi-layer IC, so that the term substrate used herein may also refer to a substrate that already contains multiple processed layers.

In the present document, the terms “radiation” and “beam” as used herein encompass all types of electromagnetic radiation, including ultraviolet radiation (e.g. with a wavelength of about 365, about 248, about 193, about 157 or about 126 nm) and extreme ultra-violet (EUV) radiation (e.g. having a wavelength in the range of 5-20 nm), as well as particle beams, such as ion beams or electron beams.

The embodiments may further be described using the following clauses:

1. A system comprising:

a lithographic apparatus including at least two sensors, each configured to measure a property related to an illumination region provided for imaging a substrate; and

a processor configured to:
determine, based on a ratio of the measured property as measured by one of the sensors in relation to the other, a drift of the illumination region with respect to a reference position;
determine, based on the drift of the illumination region, a drift in an attribute related to the illumination upstream of the illumination region measured by the at least two sensors, and
determine, based the drift in the attribute, the drift correction to be applied to the attribute to compensate for the drift in the attribute.
   2. The system of clause 1, wherein the drift correction is determined using a uniformity compensator system,
wherein the uniformity compensator system comprises one or more uniformity compensators in one or more locations in a path of the illumination region to intercept one or more corresponding portions of the illumination region in the one or more locations, and
wherein a uniformity sensitivity model determines, based on the drift of the illumination region or the drift in the attribute, an amount of adjustment to the one or more uniformity compensators to correct for the drift in the attribute.
   3. The system of clause 2, wherein the one or more uniformity compensators comprise one or more opaque finger members.
   4. The system of any of clauses 1-3, wherein the drift in the attribute is caused by one or both of illumination optics collector contamination and an amount of power of an illumination source.
   5. The system of any of clauses 1-4, wherein the drift correction is determined for each substrate within a lot.
   6. The system of any of clauses 1-4, wherein the drift in the attribute is determined by converting, based on a correlation between the drift of the illumination region and the drift in the attribute, the drift of the illumination region to the drift in the attribute.
   7. The system of any of clauses 1-6, wherein the at least two sensors comprises a first sensor located at a first location of the illumination region and a second sensor located at a second location of the illumination region.
   8. The system of any of clause 7, wherein the first sensor is located at a first end of the uniformity compensator system and the second sensor is located at a second end of the uniformity compensator system.
   9. The system of any of clauses 1-8, wherein the attribute is dose and/or pupil,

wherein the drift in the attribute is a dose drift with respect to a nominal dose, and/or a pupil drift with respect to a reference pupil, and

wherein the drift correction is a dose drift correction or a pupil drift correction.

10. The system of any of clauses 1-9, wherein the measured properties are illumination intensity values measured by a first sensor and a second sensor, respectively, of the at least two sensors.
11. The system of any of clauses 1-10, wherein the illumination region is an illumination slit.
12. The system of any of clauses 1-10, wherein the reference position is the illumination slit position measured at a start of an imaging of a substrate in a lot.
13. The system of any of clauses 1-11, wherein the reference position is at a center of the slit.
14. A method of determining a drift correction associated with a lithographic apparatus, the method comprising:

receiving, via at least two sensors, measurements of a property related to an illumination region provided for imaging a substrate;

determining, based on a ratio of the measured properties, a drift of the illumination region with respect to a reference position;

determining, based on the drift of the illumination region, a drift in an attribute related to the illumination upstream of the illumination region measured by the at least two sensors, and

determining, based the drift in the attribute, the drift correction to be applied to the attribute to compensate for the drift in the attribute.

15. The method of clause 14, wherein the drift correction is determined for each substrate within a lot.
16. The method of any of clauses 14-15, wherein the determining of the drift in the attribute comprises:

converting, based on a correlation between the drift of the illumination region and the drift in the attribute, the drift of the illumination region to the drift in the attribute.

17. The method of any of clauses 14-16, wherein the at least two sensors comprises a first sensor located at a first location of the illumination region and a second sensor located at a second location of the illumination region.
18. The method of any of clauses 14-17, wherein the attribute is dose and/or pupil,

wherein the drift in the attribute is a dose drift with respect to a nominal dose, and/or a pupil drift with respect to a reference pupil, and

wherein the drift correction is a dose drift correction or a pupil drift correction.

19. The method of any of clauses 14-18, wherein the measured properties are illumination intensity values measured by a first sensor and a second sensor, respectively, of the at least two sensors.
20. The method of any of clauses 14-19, wherein the illumination region is an illumination slit.
21. The method of any of clauses 14-20, wherein the reference position is the illumination slit position measured at a start of an imaging of a substrate in a lot.
22. The method of any of clauses 14-21, wherein the reference position is at a center of the illumination slit.
23. The method of any of clauses 14-22, wherein the determining of the correction to be applied to the attribute comprises:

executing a uniformity sensitivity model using the drift in the attribute to determine adjustments to one or more uniformity compensators,

wherein the uniformity sensitivity model determines, based on the drift of the illumination region or the drift in the attribute, an amount of adjustment to the one or more uniformity compensators to correct for the drift in the attribute.

24. The method of clause 23, wherein the drift correction for the drift in the attribute comprises:

positioning the one or more uniformity compensators in one or more locations in a path of the illumination region to intercept one or more corresponding portions of the illumination region in the one or more locations.

25. The method of any of clauses 23-24, wherein the one or more uniformity compensators comprise one or more opaque finger members.
26. The method of any of clauses 23-25, wherein a first sensor is located at a first end of a uniformity compensator and a second sensor is located at a second end of the uniformity compensator.
27. The method of any of clauses 14-26, wherein the attribute is dose and/or pupil,

wherein the drift in the attribute is a dose drift with respect to a nominal dose, and/or a pupil drift with respect to a reference pupil, and

wherein the drift correction is a dose drift correction or a pupil drift correction.

28. A non-transitory computer readable medium having instructions thereon, the instructions when executed by a computer causing the computer to:

receive, via at least two sensors, measurements of a property related to an illumination region provided for imaging a substrate;

determine, based on a ratio of the measured properties, a drift of the illumination region of the illumination region with respect to a reference position;

determine, based on the drift of the illumination region, a drift in an attribute related to the illumination upstream of the illumination region measured by the at least two sensors, and

determine, based the drift in the attribute, a drift correction to be applied to the attribute to compensate for the drift in the attribute.

29. The non-transitory computer readable medium of clause 28, wherein the drift correction is determined for each substrate within a lot.
30. The non-transitory computer readable medium of any of clauses 28-29, wherein the determining of the drift in the attribute comprises:

converting, based on a correlation between the drift of the illumination region and the drift in the attribute, the drift of the illumination region to the drift in the attribute.

31. The non-transitory computer readable medium of any of clauses 28-30, wherein the at least two sensors comprises a first sensor located at a first location of the illumination region and a second sensor located at a second location of the illumination region.
32. The non-transitory computer readable medium of any of clauses 28-31, wherein the attribute is dose and/or pupil,

wherein the drift in the attribute is a dose drift with respect to a nominal dose, and/or a pupil drift with respect to a reference pupil, and

wherein the drift correction is a dose drift correction or a pupil drift correction.

33. The non-transitory computer readable medium of any of clauses 28-32, wherein the measured properties are illumination intensity values measured by a first sensor and a second sensor, respectively, of the at least two sensors.
34. The non-transitory computer readable medium of any of clauses 28-33, wherein the illumination region is an illumination slit.
35. The non-transitory computer readable medium of any of clauses 28-34, wherein the reference position is the illumination slit position measured at a start of an imaging of a substrate in a lot.
36. The non-transitory computer readable medium of any of clauses 28-35, wherein the reference position is at a center of the illumination region.
37. The non-transitory computer readable medium of any of clauses 28-36, wherein the determining of the correction to be applied to the attribute comprises:

executing a uniformity sensitivity model using the drift in the attribute to determine adjustments to a uniformity compensator,

wherein the uniformity sensitivity model determines, based on the drift of the illumination region or the drift in the attribute, an amount of adjustment to one or more uniformity compensators to correct for the drift in the attribute.

38. The non-transitory computer readable medium of clause 37, wherein the drift correction for the drift in the attribute comprises:

positioning the one or more uniformity compensators in one or more locations in a path of the illumination region to intercept one or more corresponding portions of the illumination region in the one or more locations.

39. The non-transitory computer readable medium of any of clauses 37-38, wherein the one or more uniformity compensators comprise one or more opaque finger members.
40. The non-transitory computer readable medium of any of clauses 37-39, wherein a first sensor is located at a first end of a uniformity compensator and a second sensor is located at a second end of the uniformity compensator.
41. A lithography apparatus, the apparatus comprising:

an illumination source and illumination optics configured to image a substrate; and

at least two sensors configured to measure a property related to an illumination region provided for imaging the substrate;

a processor configured to:
determine, based on a ratio of the measured properties, a drift of the illumination region with respect to a reference position; and
determine, based on the drift of the illumination region, a drift in a attribute related to the illumination upstream of the illumination region measured by the at least two sensors, and
determine, based the drift in the attribute, a drift correction to be applied to the attribute to compensate for the drift in the attribute,

a uniformity compensator system comprising one or more uniformity compensators in one or more locations in a path of the illumination region to intercept one or more corresponding portions of the illumination region in the one or more locations, and
wherein a uniformity sensitivity model determines, based on the drift of the illumination region or the drift in the attribute, an amount of adjustment to the one or more uniformity compensators to correct for the drift in the attribute.
   42. The lithography apparatus of clause 41, wherein the drift correction is determined and applied for each substrate within the lot.
   43. The lithography apparatus of any of clauses 41-42, wherein the at least two sensors comprises a first sensor located at a first location of the illumination region and a second sensor located at a second location of the illumination region.
   44. The lithography apparatus of any of clauses 41-43, wherein a first sensor is located at a first end of the uniformity compensator system and a second sensor is located at a second end of the uniformity compensator system.
   45. The lithography apparatus of any of clauses 41-44, wherein the attribute is dose and/or pupil,

wherein the drift in the attribute is a dose drift with respect to a nominal dose, and/or a pupil drift with respect to a reference pupil, and

wherein the drift correction is a dose drift correction or a pupil drift correction.

46. The lithography apparatus of any of clauses 41-45, wherein the at least two sensors are located in a vicinity of an energy sensor that measures an intensity of the illumination region.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g. a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g. a disk) or an intangible carrier medium (e.g. a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

To the extent certain U.S. patents, U.S. patent applications, PCT patent applications or publications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions and changes in the form of the methods, apparatuses and systems described herein can be made without departing from the spirit of the present disclosures. The accompanying claims and their equivalents are intended to cover such forms or modifications as would fall within the scope and spirit of the present disclosures.

1. A system comprising:
at least two sensors of a lithographic apparatus, each configured to measure a value of property related to an illumination region provided for imaging a substrate by the lithographic apparatus; and
a processor configured to:
determine, based on a ratio of the measured values of the property as measured by one of the sensors in relation to the other, a drift of the illumination region with respect to a reference position,
determine, based on the drift of the illumination region, a drift in an attribute related to the illumination upstream of the illumination region measured by the at least two sensors, and
determine, based on the drift in the attribute, a drift correction to be applied to the attribute to compensate for the drift in the attribute.

2. The system of claim 1, wherein the drift correction is determined using a uniformity compensator system,
wherein the uniformity compensator system comprises one or more uniformity compensators in one or more locations in a path of the illumination region to intercept one or more corresponding portions of the illumination region in the one or more locations, and
wherein a uniformity sensitivity model is configured to determine, based on the drift of the illumination region or the drift in the attribute, an amount of adjustment to the one or more uniformity compensators to correct for the drift in the attribute.

3. The system of claim 2, wherein the one or more uniformity compensators comprise one or more opaque finger members.

4. The system of claim 1, wherein the drift in the attribute is caused by illumination optics collector contamination and/or an amount of power of an illumination source.

5. The system of claim 1, configured to determine the drift correction for each substrate within a lot.

6. The system of claim 1, wherein the drift in the attribute is determined by conversion, based on a correlation between the drift of the illumination region and the drift in the attribute, the drift of the illumination region to the drift in the attribute.

7. The system of claim 1, wherein the at least two sensors comprises a first sensor located at a first location of the illumination region and a second sensor located at a second location of the illumination region.

8. The system of claim 7, wherein the first sensor is located at a first end of a uniformity compensator system and the second sensor is located at a second end of the uniformity compensator system.

9. The system of claim 1, wherein the attribute is dose, the attribute is a dose drift with respect to a nominal dose, and the drift correction is a dose drift correction and/or the attribute is a pupil, wherein the drift in the attribute is a pupil drift with respect to a reference pupil, and the drift correction is a pupil drift correction.

10. The system of claim 1, wherein the measured property value are illumination intensity values measured by a first sensor and a second sensor, respectively, of the at least two sensors.

11. The system of claim 1, wherein the illumination region is an illumination slit.

12. The system of claim 1, wherein the reference position is an illumination slit position measured at a start of an imaging of a substrate in a lot.

13. The system of claim 1, wherein the reference position is at a center of an illumination slit.

14. A method of determining a drift correction, the method comprising:
receiving, via at least two sensors, measurements of values of a property related to an illumination region provided for imaging a substrate;
determining, based on a ratio of the measured values, a drift of the illumination region with respect to a reference position;
determining, based on the drift of the illumination region, a drift in an attribute related to the illumination upstream of the illumination region measured by the at least two sensors, and
determining, based on the drift in the attribute, the drift correction to be applied to the attribute to compensate for the drift in the attribute.

15. The method of claim 14, wherein the determining of the drift in the attribute comprises converting, based on a correlation between the drift of the illumination region and the drift in the attribute, the drift of the illumination region to the drift in the attribute.

16. The method of claim 14, wherein the at least two sensors comprises a first sensor located at a first location of the illumination region and a second sensor located at a second location of the illumination region.

17. The method of claim 14, wherein the attribute is dose, the drift in the attribute is a dose drift with respect to a nominal dose, and the drift correction is a dose drift correction and/or the attribute is a pupil, the drift in the attribute is a pupil drift with respect to a reference pupil, and the drift correction is a pupil drift correction.

18. The method of claim 14, wherein the measured values of the property are illumination intensity values measured by a first sensor and a second sensor, respectively, of the at least two sensors.

19. The method of claim 14, wherein the illumination region is an illumination slit.

20. A non-transitory computer readable medium having instructions therein, the instructions, when executed by a computer system, configured to cause the computer system to implement the method of claim 14.
